(19) United States
(12) Patent Application Publication
(10) Pub. No.: US 2014/0060615 A1
(43) Pub. Date: Mar. 6, 2014

(54) METHOD AND DEVICE FOR CONNECTING SOLAR CELLS TO FORM A SOLAR CELL STRING, AND A SOLAR CELL STRING

(71) Applicant: KOMAX HOLDING AG, DIERIKON (CH)

(72) Inventors: Adrian Gretler, Dierikon (CH); Stefan Kaufmann, Dierikon (CH); Adolf Hofer, Dierikon (CH)

(21) Appl. No.: 14/013,264

(22) Filed: Aug. 29, 2013

(30) Foreign Application Priority Data
Aug. 30, 2012 (EP) 12182323.1

(51) Int. Cl. H01L 31/05; H01L 31/18

(52) U.S. Cl. CPC H01L 31/0516; H01L 31/18
USPC 136/244; 438/64; 156/580; 156/514; 156/513

(57) ABSTRACT

A device for electrically connecting back surface solar cells to form a solar cell string includes an application unit for applying double-sided adhesive insulating strips to the solar cells disposed behind one another along a longitudinal axis, which insulating strips are attached to the solar cells by pressing. The device has an assembly unit for positioning electrical conductor elements on the insulating strips for connecting two adjacent solar cells. The conductor elements are flexible components for creating stress relief structures that are produced in a shaping unit disposed next to the application unit.

### FIELD

The invention concerns a method and a device for connecting solar cells to form a solar cell string. Further, the invention concerns a solar cell string. The invention is particularly suited for connecting so-called back surface solar cells, which are distinguished in that the plus and minus poles are located on the same side.

### BACKGROUND

Solar cells take advantage of the photo effect in order to produce an electrical current from radiant energy. They normally consist of silicon (or another semiconductor) and have a p-n junction, in order to separate the charge carriers. In conventional solar cells, the p-doped zone and the n-doped zone are located above one another. In order to interconnect (“string”) an array of solar cells in series, using conductors made of copper, for example, the surface facing the sun (in short, “sunny side”) of one cell must always be electrically connected to the back surface of the next cell A disadvantage of solar strings of this type is that shading of the sunny side by the electrical conductors (typically, coated copper ribbons) cannot be avoided, thus having a negative effect on the efficiency. For some time, back surface solar cells (also known as back surface contact solar cells, primarily known by their English name, “Back Contact Cells”) have been known, which, in comparison with conventional solar cells, are enjoying an increasing popularity. Because the poles (+, −) are located on the back surface with back surface solar cells (i.e. on the surface opposite the surface facing the sun), there is the advantage, compared to conventional solar cells, that on the front, not active, surface there are no, (e.g. with IBC solar cells, “Interdigitated Back Contact Cells”), or only very limited (e.g. with MWT solar cells, “Metal Wrap Through” technology), shadings. This results in a greater efficiency. In addition, the conductors on the back surface can be made to nearly any arbitrary size, without causing shading. A disadvantage is that in the production of the contacts (by means of soldering, for example) for the back surface solar cells—due to the asymmetrical assembly (silicon-copper)—there are stronger sags than with conventionally strung cells. The reason for this bimetal effect is due to the different expansion coefficients of silicon and copper, and the supply of heat necessary for the electrical connection.

It is therefore an objective of the invention to create a method and a device for connecting solar cells, with which solar cell strings can be easily and inexpensively produced. In particular, the method and the device should be suitable for connecting back surface solar cells. Furthermore, it should be possible to operate the device reliably, and the device should be distinguished by a high level of productivity. The solar strings produced in this manner should experience no, or only slight sagging as a result of the thermal load, e.g. resulting from the soldering procedure.

### SUMMARY

These objectives are attained according to the invention with a method for connecting solar cells disposed behind one another along a longitudinal axis, and in particular, back surface solar cells, to form a solar cell string, wherein the method exhibits the following steps: attachment of at least one insulating strip to the solar cell, extending at least in sections in the longitudinal axis, wherein the insulating strip applied thereto preferably exhibits or provides some free space for creating the electrical contact to the solar cells; and positioning electrical conductors, extending in the longitudinal axis, on the at least one insulating strip, for connecting two respective neighboring solar cells, wherein the conductors can be connected to the solar cells via the free space mentioned above. The insulating strip can be designed to be continuous, and can extend over the entire length of the solar cell string. This also has the advantage that no additional element is necessary for the frequently desired coating of the electrical conductors between the solar cells. Alternatively, the respective insulating strip can also be partitioned into insulating sections, wherein each insulating section can be allocated to one solar cell of the solar cell string. It is advantageous that the insulating strip is comparatively narrow in relation to the width of the solar cells, as a result of which, the expenditure in terms of material can be significantly reduced. Insulating strips of this type are inexpensive and can be obtained in different widths, thicknesses and compositions, or can be readily produced, and can be optimally adapted to the respective use.

The insulating strip substantially consists of a material that is not, or is only slightly, electrically conductive, and is preferably made of a flexible plastic material.

In a first embodiment, the insulating strip is designed as a double-sided adhesive strip, which is attached to the solar cells by means of pressure. The attachment is preferably on the back surface of the solar cell thereby (i.e. the surface facing away from the surface facing the sun). An insulting strip of this type can be particularly easily applied to the solar cell, in a single production step, A prior application of adhesive is clearly not necessary. A particular advantage is that the conductor can, at least provisionally, be attached to the insulting strip simply by pressing it in place, preferably such that it cannot detach therefrom, and attached to the solar cells provided with insulating strips, more or less automatically, and in a reliable manner. Commercially available double sided adhesive strips with insulating properties may be used, which can be obtained, for example, in rolls, thus also having cost-saving benefits. The base material for these strips may consist of plastic (e.g. PP, PE, PET, PTFE), coated on both sides with an acrylic adhesive, for example.

Furthermore, it may be advantageous if the at least one insulating strip is provided with openings or holes, in order to create the free space for establishing an electrical contact to the solar cells, wherein the providing with holes preferably occurs during the feeding of the insulating strip to the solar cells. A design of this type ensures that different sizes and types of solar cells can be readily processed, using the same starting insulating strip material. It is, of course, also conceivable to use pre-manufactured insulating strips, which already contain holes. The free spaces could alternatively be formed by interruptions between individual, short insulting strip sections, disposed successively in the longitudinal axis.

The conductors can be conductor elements in the shape of strips, designed as flexible components for creating stress relief structures, made of highly conductive metal (e.g. copper). Copper bands can be used, for example, which are plated with tin (coated with lead) or silver. Other materials (such as aluminum) are also conceivable, however. These stress relief structures prevent an undesired, thermally effected sagging of the solar cells in a subsequent contacting procedure, by means of soldering, for example, or welding. As relief structures, the conductors may be curved, or exhibit springs, which compensate for expansions caused by heat. The specified conductor elements, designed as flexible components, are preferably made of narrow metal bands, which are plastically deformed by means of shaping procedures. The metal bands, and therefore, the conductor elements can, for conventional solar cells, be between 0.01 mm and 1 mm thick, and 0.5 mm to about 50 mm wide. These consist of copper bands, which are normally tin-plated (coated with lead), or in some cases, are silver-plated.

If the electrical conductors for the electrical connection of the solar cells are strip-shaped conductor elements (“conductor ribbons”), it may be advantageous if the conductor elements are drawn, preferably from a metal strip roll, and subsequently cut to length and shaped to create the stress relief structures. For this, the cutting and shaping procedures, preferably using a shaping unit, containing bending punches and bending dies, can preferably occur simultaneously. The simultaneous cutting and creating of the stress relief structures using the shaping unit may also be advantageous without the use of the aforementioned insulating strip.

The device according to the invention for the electrical connection of solar cells and in particular of back surface solar cells, to form a solar cell string exhibits an application unit for applying at least one insulating strip to the solar cells disposed behind one another along a longitudinal axis, wherein the applied insulting strip preferably exhibits or provides free spaces for creating the electrical contact to the solar cells. Furthermore, the device exhibits an assembly unit for positioning electrical conductors, used to connect two adjacent solar cells to one another, on the at least one insulating strip, wherein the conductors can preferably be connected to the solar cells via the aforementioned free spaces.

If the at least one insulating strip is designed as a double sided adhesive strip, it may be advantageous that the application unit exhibits a means for pressing the insulating strip onto the solar cells. The pressure means can be a relatively immobile component having a sliding surface, on which the insulating strip can be fed, and which, at least in sections, presses against the back surface of the solar cells with a means for obtaining a preload force, for example. It is to be understood that the pressure means can also be designed differently. It would be conceivable, for example, to use a freely rotating deflection roller for the insulating strip, which can unwind over the back surface of the solar cell.

The device can exhibit a hole making station for providing the openings in the insulating strip. The hole making station can be disposed thereby, advantageously, between an insulating strip roll, mounted so as to be freely rotating at a right angle to the longitudinal axis, and the application unit. The hole making station can exhibit means for punching or cutting openings in the insulating strip.

The solar cells can exhibit two or three rows of contact zones disposed next to one another, which are oriented basically parallel to one another in the longitudinal axis. Each row of contact zones can have a plus or minus pole allocated to it thereby. In this case, it may be advantageous if the device exhibits one application unit for each row of contact zones, and if applicable, a hole making station, wherein the application units can be disposed in a row next to each other, or offset to one another, in relation to the longitudinal axis. It can be particularly advantageous if the application units are disposed offset to one another such that the respective application units are each allocated to one of three solar cells disposed behind one another.

In another embodiment, the device can exhibit at least one supply roll or reel for providing material for producing the conductor, from which conductor material can be drawn by means of a drawing unit.

The drawing unit can exhibit at least one gripper, for grabbing, in a clamping manner, the free end of the conductor material from the supply roll.

Furthermore, it may be advantageous if the device exhibits a shaping unit for creating the stress relief structures for the conductor elements. Using the shaping unit, flat attachment sections and contact sections of the conductor element can be produced in a simple manner, preferably lying in a common plane. The conductor elements can be produced from a narrow copper band. A shaping unit of this type can also be used in other devices for connecting solar cells. A device of this type could, for example, exhibit an application unit for coating the solar cells with an insulating material. This shaping unit could even be advantageous for conventional stringers, in which a surface facing the sun is connected to a back surface in each case. In this case, the device for the electrical connection of solar cells would comprise an assembly unit for positioning electrical conductors on the solar cells in order to connect two neighboring solar cells, and a shaping unit for creating the stress relief structures of the conductor elements.

The shaping unit can contain a bending die and a bending punch, wherein at least the bending die has a two-part design, and wherein the two bending die parts can be displaced in relation to one another, in order to adjust the lengths of the conductor elements in the longitudinal axis. With a configuration of this type, an efficient operation and broad field of use is ensured, and an exchange of the shaping tool for refitting for different solar cell sizes is not necessary.

Furthermore, it may be advantageous if the shaping unit contains a bending die and a bending punch, wherein the bending die and the bending punch each have a two-part design. The bending die parts and the associated punch parts can be displaceable in relation to one another at a right angle to the longitudinal axis, in pairs, for forming a deformation of the conductor element in the transversal direction. This can be useful for preventing any possible turning of the solar cells in relation to the orientation of the row of contact zones having the same polarization.

The shaping unit can be a component of a punching station, by means of which the conductor element, aside for the shaping procedure, can be cut to the desired length. The cutting means can be integrated thereby in the bending die or the bending punch by means of a corresponding shaping. Of course, the punching station could also exhibit a separate blade, which can be operated independently of the shaping unit, for cutting the conductor elements to length.

Furthermore, the device can exhibit a conveyor device for conveying the solar cells, disposed behind one another, in the longitudinal direction. For this, the application unit can be disposed above or below the conveyor device, such that the at least one insulating strip is attached to the solar cells during the conveyance procedure.

The shaping unit and, if applicable, the punching station, can be disposed, in relation to the longitudinal axis, next to the conveyor device. The conductor elements can be removed from the punching station by means of an assembly unit functioning according to a pick-and-place procedure, and deposited on the at least one insulating strip.

Another aspect of the invention concerns a solar cell string, which is preferably produced according to the method described above and/or using the device described above. The solar cell string exhibits solar cells disposed successively along a longitudinal axis. Preferably, this concerns back surface solar cells thereby. The solar cell string exhibits at least one insulating strip disposed on the solar cells, extending in the longitudinal axis, and electrical conductors extending in the longitudinal axis, attached to the insulating strip, which each electrically connect two adjacent solar cells to one another. The insulating strip can exhibit openings or other free spaces, by means of which the electrical conductors are each applied to a contact location on the back surfaces of the solar cells, for creating an electrical contact. The insulating strip can be continuous over all of the cells in a string, and thus cover the electrical conductor, such that are not visible when the solar module is fully assembled.

The conductors can each be strip shaped conductor elements, which are designed as curved components in order to create stress relief structures. The conductor elements can each exhibit at least one flat attachment section, which lies on the insulating strip, as well as, if applicable, flat contact sections, which lie on the solar cells in the regions of the contact locations.

### DESCRIPTION OF THE DRAWINGS

Further individual characteristics and advantages of the invention can be derived from the following description of embodiment examples, and from the drawings. They show:

FIG. 1 is a perspective depiction of a device, according to the invention, for connecting solar cells in a solar cell string;

FIG. 2 shows an application station with application units for attaching insulating strips to the solar cells in an enlarged depiction (detail A from FIG. 1);

FIG. 2a shows an application unit according to an alternative embodiment example to that in shown in FIG. 2;

FIG. 3 shows a punching station having a shaping unit and a drawing unit for producing conductor elements to be attached to the solar cells (enlarged detail B from FIG. 1);

FIG. 4 shows an assembly unit for positioning the conductor elements on the insulating strips and a soldering station (enlarged detail C from FIG. 1),

FIG. 5A shows the punching station with an open shaping unit and a drawing unit in a starting setting;

FIG. 5B shows the punching station with drawn out material for producing the conductor elements;

FIG. 5C shows the punching station in the closed setting;

FIG. 6A shows the punching station from FIG. 5A, however with the bending die parts of the shaping unit pulled apart from one another;

FIG. 6B shows the punching station after drawing out the conductor material for the conductor elements;

FIG. 6C shows the punching station in the closed setting;

FIG. 7 shows a closed shaping unit in another working setting;

FIG. 8 shows the shaping unit from FIG. 7 with the front punching part removed;

FIG. 9 is an enlarged detail depiction of the shaping unit from FIG. 8;

FIG. 10 shows a section of a solar cell string produced using the device according to the invention, in an enlarged depiction;

FIG. 11 shows an alternative solar cell string according to the invention; and

FIG. 12 shows another solar cell string according to the invention.

### DETAILED DESCRIPTION

The following detailed description and appended drawings describe and illustrate various exemplary embodiments of the invention. The description and drawings serve to enable one skilled in the art to make and use the invention, and are not intended to limit the scope of the invention in any manner. In respect of the methods disclosed, the steps presented are exemplary in nature, and thus, the order of the steps is not necessary or critical.

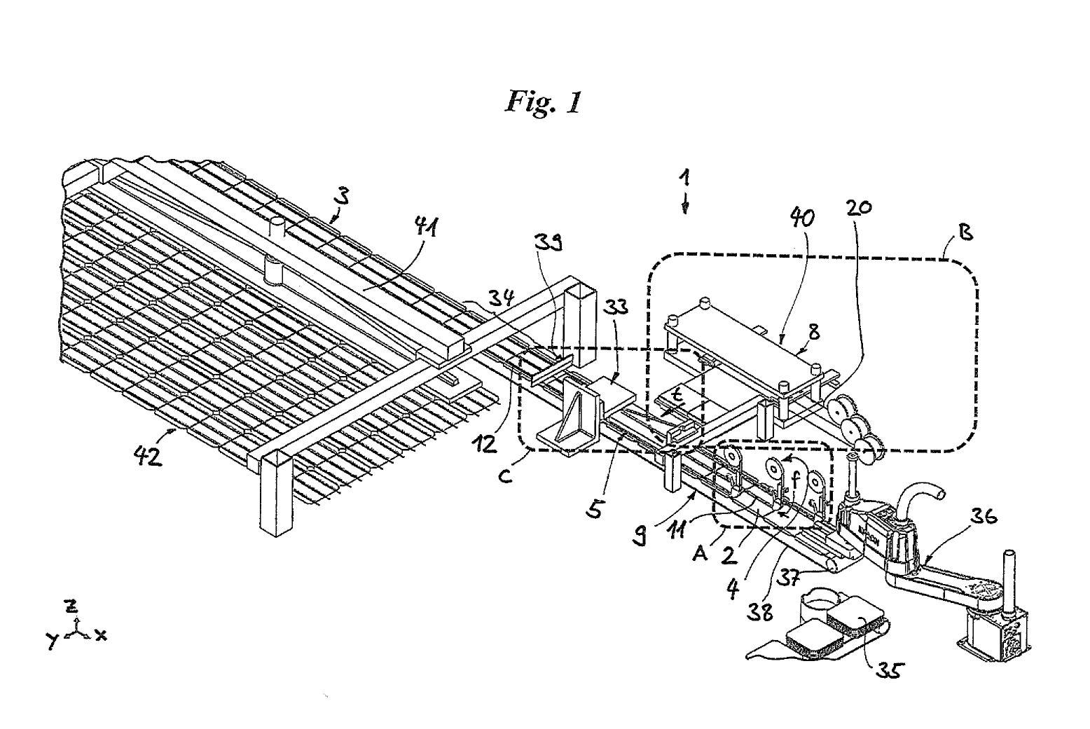

FIG. 1 shows a device, indicated as a whole with the numeral “1,” for the electrical connection of solar cells to form a solar cell string 3. The device 1 has a conveyor device 9 with which the solar cells 2, disposed behind one another, are conveyed in the longitudinal direction indicated by the arrow “x” to or through the device 1 in the f-direction (arrow). The conveyor device 9 is presently designed as a conveyor belt, equipped with a vacuum belt. In FIG. 1, the conveyor belt 38 and a deflection roller 37 in the front region of the conveyor belt can be seen. Of course, other conveyor means, such as a lifting beam (“walking beam”), would also be conceivable. By means of a robot 36, exhibiting a pivotal arm, individual solar cells are removed from a stack 35 of solar cells, and deposited on the conveyor belt of the conveyor device 9. The robot 36 is also capable of rotating the solar cells 180° if required, thus changing the orientation thereof. The solar cells 2 then first pass through an application station, which exhibits three application units 4. The insulating strips 11 are attached to the solar cells 2 by means of the application units 4. After passing through this application station, the solar cells exhibit insulating strips 11 running parallel to one another along the x-axis, or the longitudinal axis. Instead of the three parallel insulating strips, it is of course possible to have only two or even just one insulating strip attached to the solar cells.

Back surface solar cells are processed using the illustrated device. The solar cells are placed on the conveyor belt 38 thereby in the embodiment example according to FIG. 1, such that the back surfaces (i.e. the surface facing away from the surface facing the sun, or the active surface, respectively) are facing up and are exposed. At least one insulating strip 11 can be applied to individual ones of the solar cells 2 or can be applied as a continuous strip to multiple solar cells disposed' one behind the other as they are conveyed through the device 1.

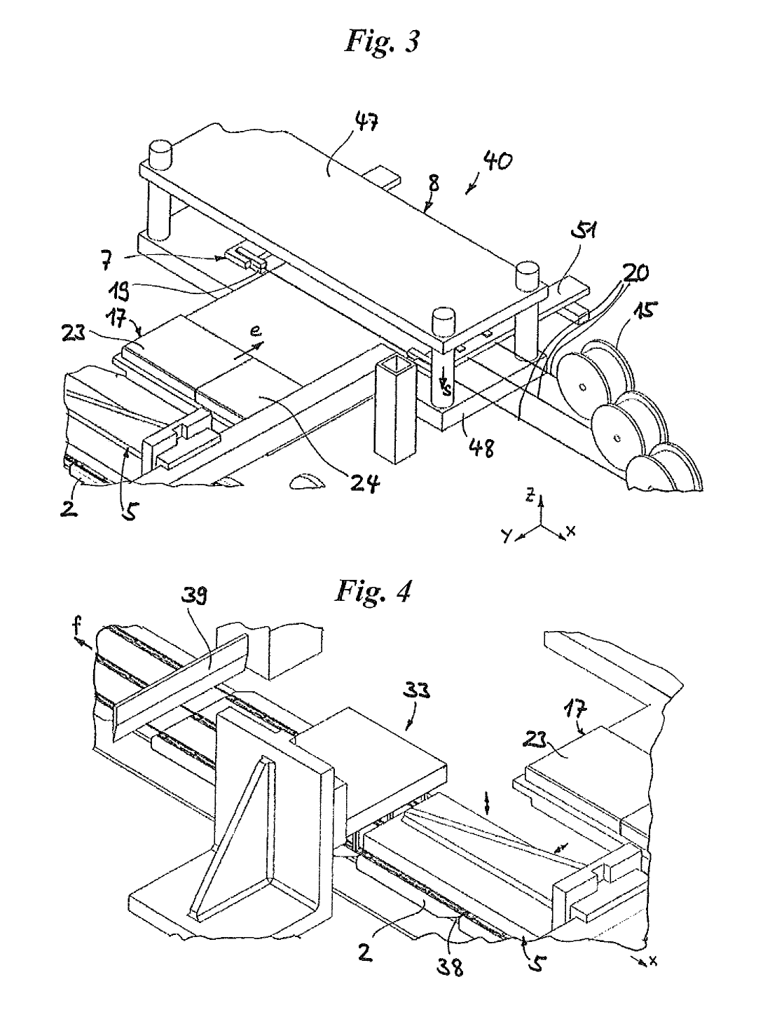

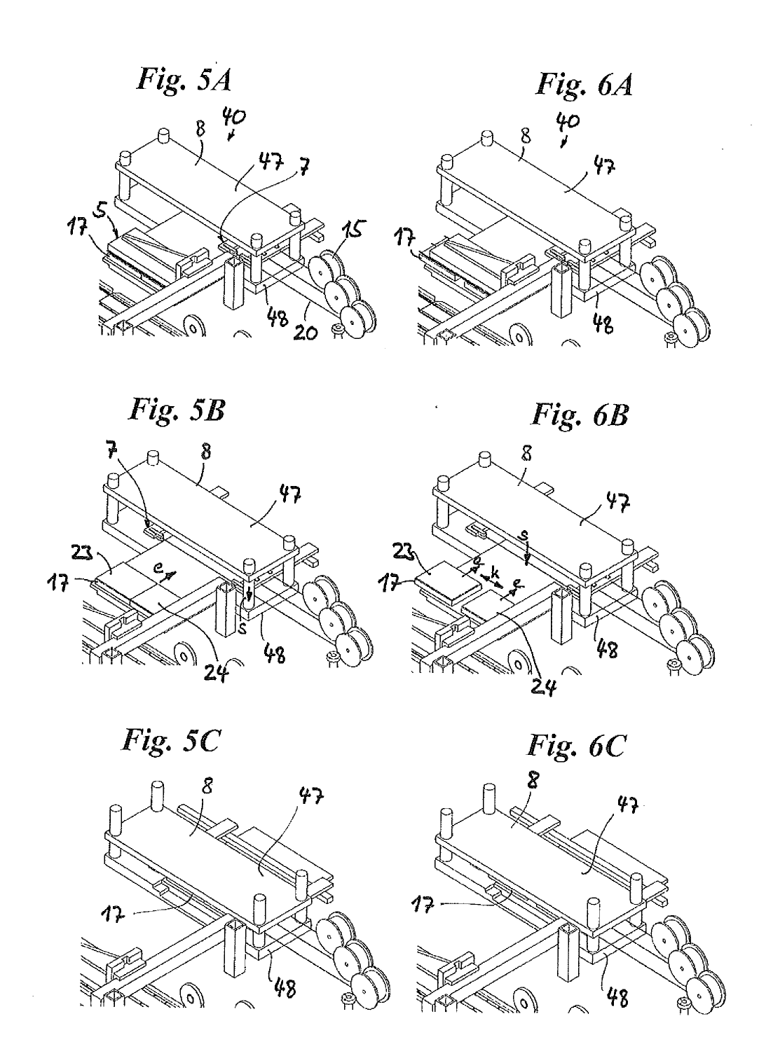

The device 1 furthermore comprises a punching station, indicated by the numeral “40,” which is disposed next to the conveyor device 9. Conductive material containing strip-shaped copper, for example, (e.g. tin-plated copper bands) is processed in the punching station 40 to form conductor elements. The copper bands are between 0.01 mm and 1 mm thick, and have a width of 0.5 mm to up to 50 mm. Details regarding the design of the punching station can be derived from the following FIG. 3 as well as FIGS. 5A-C and 6A-C. The finished conductor elements made of copper are then transferred by means of an assembly unit 5 from the punching station 40 to the solar cells 2 and are each positioned on the solar cells in the region of the insulating strips 11. The solar cells, now equipped with conductor elements, then pass through a soldering station 33 having a pre-heating zone; a downstream cooling area is indicated by the numeral 34. Instead of the soldering procedure executed in the station 33 (using hot air, induction or by means of contact), other contacting or connecting methods for completing the electrical connection between the conductor and the solar cell, such as laser welding, ultrasound welding or gluing, can be considered. The solar cell string created in this manner is then cut to the desired length by means of a cutting blade 39. A completed solar cell string is indicated with the numeral 3. Solar cell strings 3 can then be combined in the lay-up station with a transferring device 41 to form a solar module in a matrix 42.

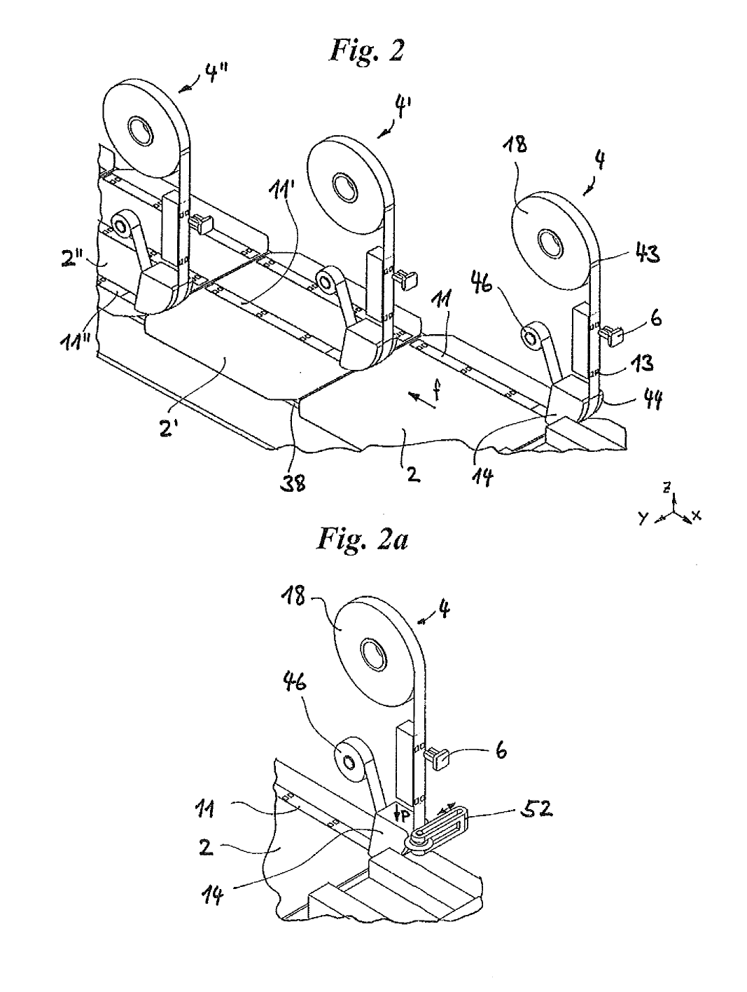

Details of the application station can be discerned in FIG. 2, by means of which the insulating strips are applied to the solar cells 2. The application station contains three application units, wherein a first application unit is indicated with the numeral 4, and the subsequent ones are indicated with the 4′ and 4″. It is clear that in the present embodiment example, the individual application units 4, 4′, 4″ are disposed offset to one another. Of course, other configurations are also possible, such that, for example, the application units could be disposed next to one another, in the same position with respect to the longitudinal axis. Each application unit contains a supply roll 18, from which the insulating strip can be removed and applied to the solar cells. In the embodiment example depicted here, the insulating strip is already separated on the supply roll 18 into single insulating strip sections 11 corresponding to the dimensions of the solar cells. The separation points between the individual insulating strips, or insulating strip sections 11, respectively, are indicated with the numeral 43. During the feeding of the insulating strip from the supply roll 18 onto the solar cells 2, two adjacently disposed openings 13 are made in the insulating strip, by means of punching, in a hole making station 6, by way of example. The openings 13 provide free spaces, by means of which the (not shown here) electrical conductors are electrically connected to the positive and negative contact points on the back surfaces of the solar cells. The creation of the openings 13 can, of course, also be carried out by other means, such as laser cutting, for example. Moreover, it would be conceivable to apply positioning markings on the insulating strips.

The insulating strips 11, separated into single sections, are designed as double-sided adhesive strips, which can be attached to the solar cells simply by pressing. The insulating strips 11 consist, for example, of an insulating plastic (e.g. PP, PE, PET, PTFE), which is coated on both sides with an acrylic adhesive, for example. The insulating strip is guided along a sliding surface 44 of a pressing element 14, and redirected. The pressing force, indicated by an arrow P in FIG. 2a, occurs, for example, by means of a (not shown) spring-loaded element, which presses downward on the pressing component 14. In a starting position, the insulating strip, coated on both sides with an adhesive, rolled up on the supply roll 18, is protected by a liner strip. Rollers, indicated with the numeral 46, are used to roll up the liner strips removed from the insulating strip.

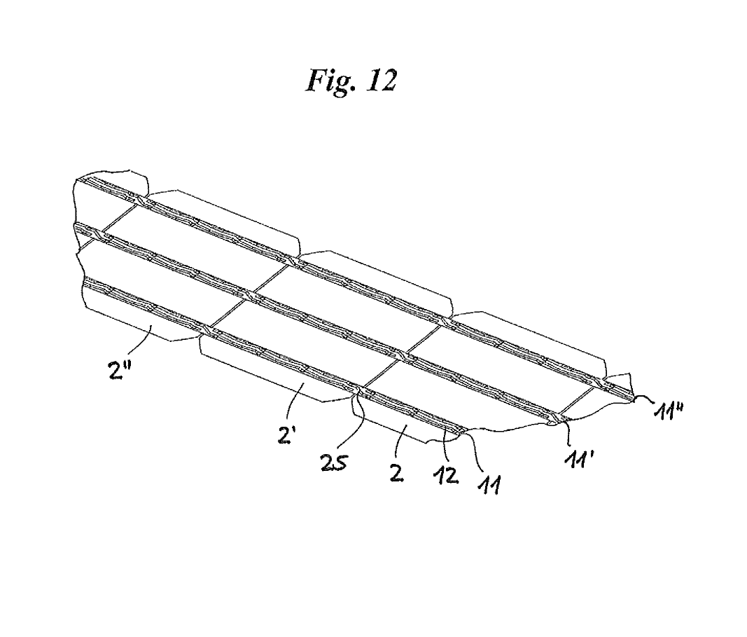

The insulating strip material rolled onto the supply role need not necessarily be prepared in advance, and already exhibit separation locations. The insulating strip material can, for example, be cut into single strip sections during the feed process. A structural solution in this regard is shown in FIG. 2a, By means of a cutting device, having a circular blade that can be moved back and forth at a right angle to the running direction of the strip, the strip material can be cut into sections. It may, however, also be advantageous to not separate the insulating strip into individual sections, and to leave it as a continuous strip (cf. FIG. 12).

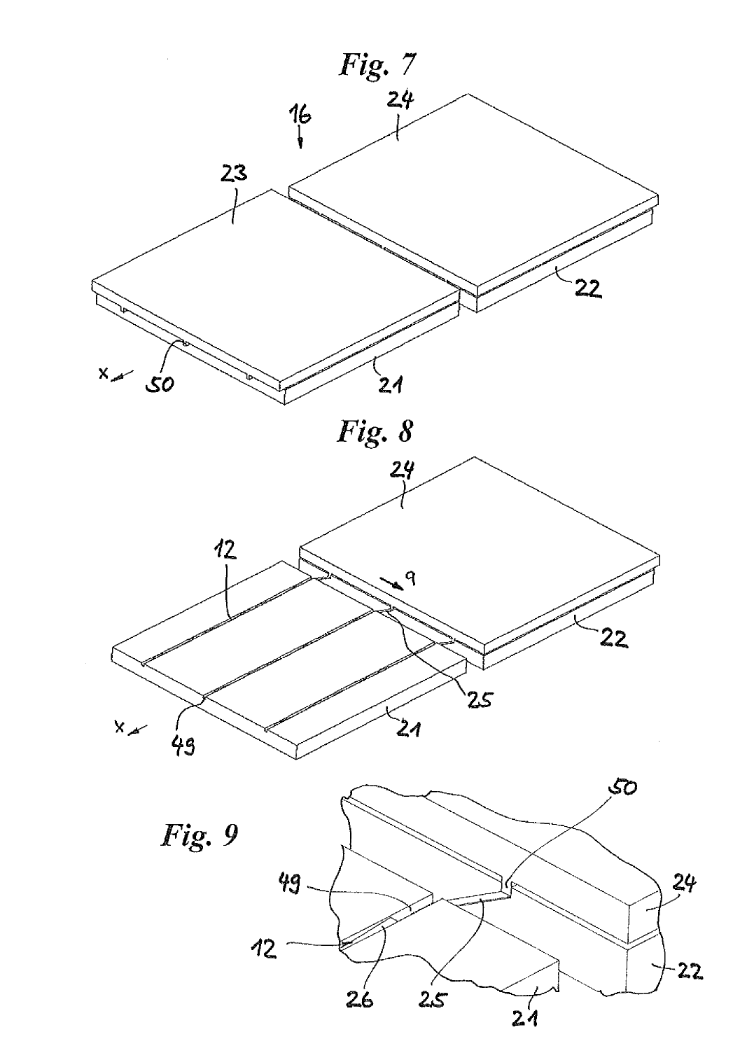

FIG. 3 shows the punching stations 40. This substantially comprises a shaping unit 8, containing a two-part bending die 17, and a bending punch, which can be moved up and down in the z-axis. The bending punch cannot be discerned, at least in FIGS. 1, 3 as well as 5A-C and 6A-C, because it is hidden by an upper plate 47. This plate 47 serves as a shoring for the bending punch in the upward direction (cf. FIG. 7 as well). The lower plate 48 serves as a bearing for the bending die 17. The conductor elements are produced from a narrow, strip-shaped material, having a width of only a few millimeters, and preferably made of copper. The conductor material 20, coming from a roll 15 or a spool, is grasped by means of grippers 19 in a drawing unit 7, and positioned between the bending die 17 and the bending punch 16 (FIG. 7) by means of a drawing motion. At this point, the bending punch is moved in the engagement direction, indicated by the arrow “s”, against the bending die 17, by means of which a conductor element exhibiting a stress relief structure, designed as a flexible component, is obtained. For the shaping procedure, however, the bending die 17 must also be moved in the e-axis beneath the bending punch 16. Furthermore, the conductor elements must be cut to the correct lengths. The metal bands are held in place between the drawing unit 7 and the retaining and cutting device 51, comprising grippers, and cut to length. Alternatively, the punching station 40 could also have a cutting element on the bending die side, for cutting the strips to length. The bending die 17 is disposed in the device 1 such that it can be displaced transversally to the longitudinal axis. In the depiction according to FIG. 3, the bending die is located in a displaced position in relation to the bending punch, next to the bending die 16. In this position, the shaped (not shown) conductor elements can be retrieved by the assembly unit 5, and transported for attachment to the solar cells.

The two-piece design of the shaping unit 17 enables the production of conductor elements of different lengths, without it being absolutely necessary to cut off parts of the conductor material. It should be noted that the first and the last conductor elements of a solar cell string are normally shorter than the strips between them, because the latter each connect two solar cells to one another. The starting and end conductor elements are preferably each produced at the same time. For this, an offset (cf. the following FIG. 6A) must be carried out with the bending die in the longitudinal axis.

It can be seen from FIG. 4, among other things, that the assembly unit 5 extends in the longitudinal axis “x”, or in the direction of travel “f”, respectively, over two solar cells at the same time. The same applies substantially for the shaping unit 8. The assembly unit 5 can move up and down and back and forth in the transverse direction. The respective movement directions are indicated in FIG. 4 by means of double arrows. The completed conductor element is removed from the punching station 40 by means of the assembly unit 5, transferred to the solar cells at a right angle to the conveyor device, and then glued to the insulating strip, provided with openings, and adhesive on both sides, by means of simply pressing. The assembly unit 5 is equipped, for example, with vacuum suction devices for picking up the conductor element. Furthermore, the soldering station 33 and cutting station, with the blade 39, can be discerned in FIG. 4. If necessary, a pre-heating station can also be located upstream of the soldering station 33, in which the solar cells, and in part, the conductors as well, are heated from below.

FIGS. 5A to 5C show the individual sequences for the production of the conductor elements using the punching station 40. In the starting position shown in FIG. 5A, the free ends of the conductor material 20 are grasped by grippers 19 (FIG. 3) in the drawing unit 7, and then drawn out in the longitudinal direction. The drawing motion is indicated by the arrow “f” (FIG. 4). Because the conductor elements are to connect two solar cells to one another, the conductor material must be drawn out far enough that the conductor elements can be produced at a length of two solar cells plus a possible spacing between the solar cells. After this, the drawing unit 7 is located in the position shown in FIG. 5B. The bending die 17 is then moved in the e-axis to a shaping position beneath the bending punch, whereupon the bending punch 16 is moved against the bending die 17 for the actual shaping procedure. The engaging direction is indicated thereby with the arrow “s”. FIG. 5C shows the punching station 40 with the shaping unit 7 in an engaged setting. By means of the cutting element 51 on the bending die end, the conductor elements are cut to length by cutting the conductor material at the same time that the shaping process is carried out.

FIGS. 6A-6C show a slightly modified process for the production of a conductor element. As can be seen in FIG. 6B, the two bending die parts can move in relation to one another, and can be moved away from one another in the longitudinal axis. This functionality is indicated with the double arrow “k”. By moving one of the punch-die pairs 21, 23 or 22, 24 (FIG. 7) or by means of a simultaneous moving of the punch-die pairs 21 and 23, or 22 and 24, respectively, these are separated from one another. By this means, it is possible to vary the lengths of the conductor elements.

It is clear, once again, from FIG. 7, that both the bending die 17 as well as the bending punch 16 are each designed as two-piece components. The bending die consists, accordingly, of the two bending die parts 21 and 22, and the bending punch 16 consists of the two punch parts 23 and 24. The bending die parts 21 and 22 each contain grooves 49 (FIG. 8), in which the conductor material can be accommodated. The groove base of the groove 49 is pre-shaped thereby for forming the stress relief structures. The punch parts 23 and 24 have projections 50, designed to be complimentary to the groove 49, which are shaped as an integral part of the punch parts. By means of a transversal motion, indicated by the arrow “q” (FIG. 8), the bending die part-punch part pair 22, 24 can be displaced such that a shaping 25 occurs. The conductor material that is to be shaped is guided into the grooves 49 of the bending die, and fixed in place, in order to prevent a possible buckling. This shaping 25 enables a connection of the plus contacts of one solar cell to the minus contacts of a subsequent solar cell, without having to rotate every second cell 180°. This can, in particular, be advantageous if the number of plus contacts in a series parallel to the conductor elements is not the same as the number of minus contacts in a series parallel to the conductor elements.

The device described above also enables a continuous connecting (“stringing”) of back surface solar cells, wherein, in each case, a string can be formed having the plus pole in one direction and the minus pole in the other direction. The next string is then produced such that its polarity is the reverse thereof. This corresponds to the configuration in a solar module, and enables a higher throughput during the lay-up, because the string no longer needs to be rotated for the lay-up, but instead, needs only to be displaced. In order to produce this positive characteristic, the first cell of the new string must be applied in the same manner as the last solar cell in the previous string. The polarity can be determined by rotating the solar cells 180° by means of robots 36 (FIG. 1).

The completion stations and units of the device described above, and shown in the figures can also be spatially separate from one another, in order to be able to carry out the individual procedures in parallel, thus generating the highest possible throughput.

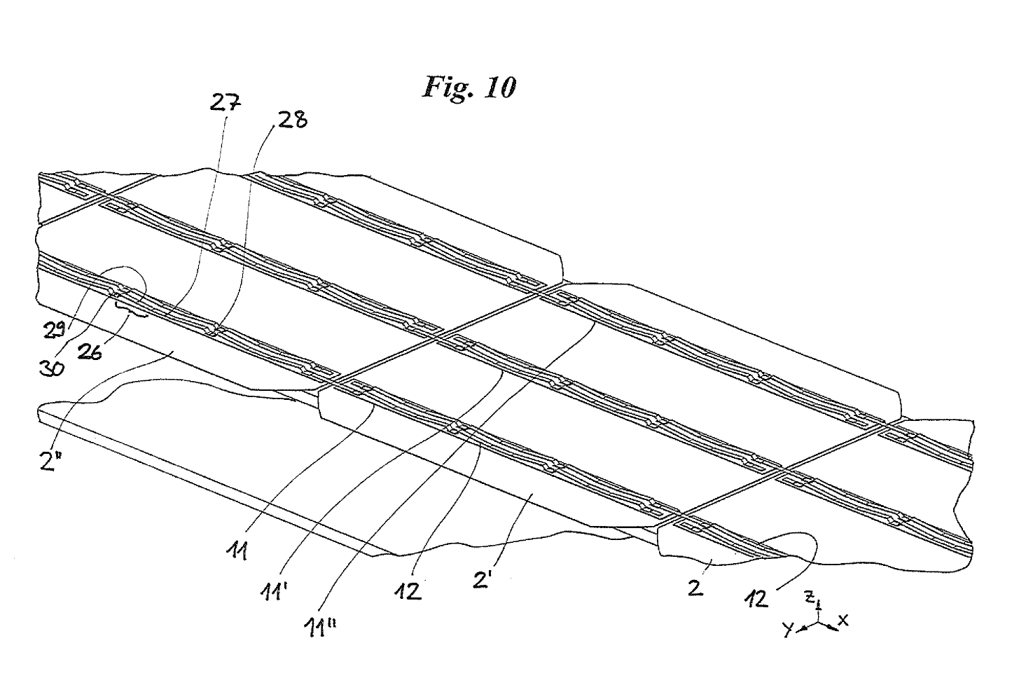

FIG. 10 shows a section of a solar cell string, with solar cells 2 connected electrically by means of the conductor elements 12, which the conductor elements 12 each extend over two solar cells and exhibit numerous (six in this case) planar attachment sections 27, which lie flat on the insulating strips 11, and are attached thereto. By this means, it is ensured that the conductor elements can be glued in a precise manner to the double-sided adhesive and insulating strip 11. Furthermore, the conductor elements 12 exhibit stress relief structures 26, designed as arches, each of which are composed of a first arc section 29 and a comparatively shorter arc section 30. Contact sites are provided on each solar cell for each longitudinal row. The configuration of the stress reliefs and the attachment sections can also be designed differently. The insulation strips 11 exhibit openings 13 corresponding to the contact zones, by means of which the respective conductor elements 12 make direct contact with the contact sites of the solar cells 2. The conductor elements exhibit flat contact sections 28 in order to provide a good electrical connection. The present conductor element configuration can be obtained if every second solar cell is rotated 180° in relation to the solar cells 2, 2′, 2″ disposed behind one another.

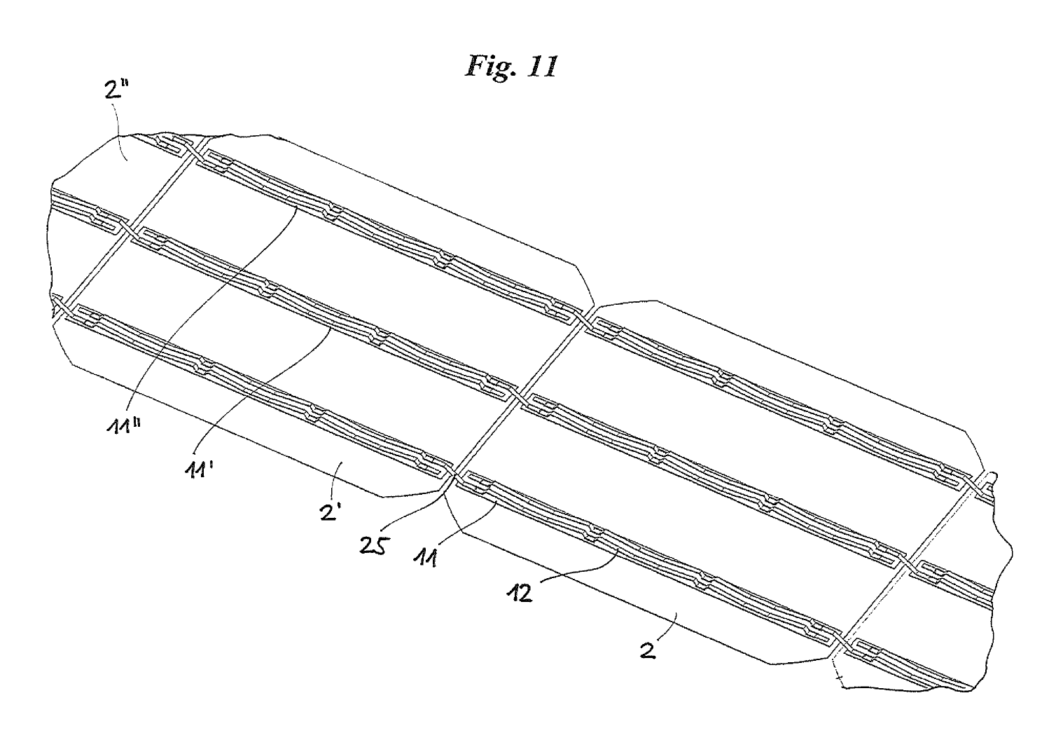

It is clear that with the device it is also possible to create a solar cell string in which the solar cells, disposed behind one another, or in rows next to one another, respectively, have the same orientation. FIG. 11 shows a section of a solar cell string of this type, having conductor elements 12, each of which exhibits a deformation 25 in the center, running at a diagonal to the transversal axis, which are produced according to the method as set forth in FIGS. 7-9.

The solar cell string shown in FIG. 12 exhibits a conductor 12 configuration similar to that in the string shown in the embodiment example according to FIG. 11, and differs from this only in that an insulating strip 11, 11′, 11″ extending over all of the solar cells 2, 2′, 2″ is used. An advantage of having these continuous insulating strips extend over the entire string is that the conductor elements are covered in the free space between the solar cells, and thus protected.

In accordance with the provisions of the patent statutes, the present invention has been described in what is considered to represent its preferred embodiment. However, it should be noted that the invention can be practiced otherwise than as specifically illustrated and described without departing from its spirit or scope.

What is claimed is:

1. A method for connecting back surface solar cells to form a solar cell string, comprising the steps of:
applying at least one insulating strip to back surfaces of a plurality of back surface solar cells disposed behind one another extending in a direction of a longitudinal axis; and
positioning and attaching electrical conductors on the at least one insulating strip extending in direction of the longitudinal axis to connect two adjacent ones of the solar cells.

2. The method according to claim 1 wherein the at least one insulating strip is formed as a double-sided adhesive strip and is attached to the solar cells by pressing.

3. The method according to claim 1 wherein the at least one insulating strip is provided with openings creating free spaces for establishing an electrical contact to the solar cells, wherein the openings are formed while feeding the at least one insulating strip to the solar cells.

4. The method according to claim 1 wherein the conductors are conductor elements made of a metal material shaped as a strip and have stress relief structures formed therein.

5. The method according to claim 4 wherein the conductor elements are drawn from a metal band roll and subsequently cut to length and shaped to create the stress relief structures, wherein the cutting to length and the shaping occur at the same time using a bending punch and a bending die containing a shaping unit.

6. A device for electrically connecting back surface solar cells to form a solar cell string, comprising:
an application unit for applying at least one insulating strip to back surfaces of a plurality of back surface solar cells disposed behind one another along a longitudinal axis; and
an assembly unit for positioning conductor elements on the at least one insulating strip, each of the conductor elements connecting two adjacent ones of the solar cells.

7. The device according to claim 6 wherein the at least one insulating strip is a double-sided adhesive strip, and the application unit presses the at least one insulating strip onto the back surfaces of the solar cells.

8. The device according to claim 7 including a hole making station for providing openings in the at least one insulating strip.

9. The device according to claim 6 wherein the solar cells each have at least two rows of contact sites disposed next to one another, and including a separate one of the application unit for each row of the contact sites, wherein the application units are disposed in a row next to one another, or offset to one another with respect to the longitudinal axis.

10. The device according to claim 6 including a supply roll for supplying conductor material for producing the conductor elements, and a drawing unit for drawing the conductor material from the supply roll.

11. The device according to claim 10 wherein the drawing unit has at least one gripper for gripping a free end of the conductor material from the supply roll in a clamping manner.

12. The device according to claim 6 including a shaping unit for creating stress relief structures in the conductor elements.

13. The device according to claim 12 wherein the shaping unit includes a bending die and a bending punch, wherein at least one of the bending die and the bending punch is a two-part component, and the two parts can be displaced in relation to one another in order to adjust a length of the conductor elements in the longitudinal axis.

14. The device according to claim 12 wherein the shaping unit includes a bending die and a bending punch, wherein the bending die and the bending punch are each two-part components, and the bending die parts and the punch parts can be displaced in relation to one another in pairs to form a deformation in the conductor elements in a transversal axis at a right angle to the longitudinal axis.

15. The device according to claims 12 wherein shaping unit is a component of a punching station which, along with the shaping of the conductor elements cuts the conductor material to a predetermined length.

16. The device according to claim 12 including a conveyor for conveying the solar cells disposed behind one another in a direction of the longitudinal axis, wherein the application unit is disposed above or below the conveyor wherein the at least one insulating strip is applied to the back surfaces of the solar cells during conveyance by the conveyor.

17. The device according to claim 16 wherein a punching station is disposed adjacent to the conveyor, and the conductor elements are removed from the punching station by an assembly unit and deposited on the at least one insulating strip.

18. A solar cell string having a plurality of back surface solar cells disposed behind one another along a longitudinal axis, at least one insulating strip extending in a direction of the longitudinal axis and disposed on back surfaces of the solar cells, and at least one conductor element extending in the direction of the longitudinal axis and attached to the at least one insulating strip, which at least one conductor element electrically connects two adjacent ones of the solar cells to one another.

19. The solar cell string according to claim 18 wherein the at least one conductor element is a strip-shaped conductor element made of metal and having a stress relief structure formed therein, and wherein the conductor element has at least one flat attachment section lying on the at least one insulating strip.
